(19) United States
(12) Patent Application Publication
(10) Pub. No.: US 2025/0007483 A1
(43) Pub. Date: Jan. 2, 2025

(54) LAMINATED COMMON MODE FILTER

(71) Applicant: AMOTECH CO., LTD., Incheon (KR)

(72) Inventors: Byungguk LIM, Incheon (KR); Heehwang KIM, Incheon (KR)

(73) Assignee: AMOTECH CO., LTD., Incheon (KR)

(21) Appl. No.: 18/708,354

(22) PCT Filed: Nov. 4, 2022
(86) PCT No.: PCT/KR2022/017227

§ 371 Date: May 8, 2024

(30) Foreign Application Priority Data
Nov. 10, 2021 (KR) 10-2021-0153712

(51) Int. Cl. H03H 7/01; H01F 27/28; H01F 27/29; H01F 27/40; H01G 4/30

(52) U.S. Cl. CPC H03H 7/0115; H01F 27/2804; H01F 27/292; H01F 27/40; H01G 4/30; H01F 2027/2809

(57) ABSTRACT

Disclosed is a laminated common mode filter which implements a wide band characteristic and in which the resistance and inductance of coil patterns configuring each channel are formed uniformly. The disclosed laminated common mode filter comprises: an upper electrode layer configured by a lamination comprising multiple coil patterns; a lower electrode layer configured by a lamination comprising multiple coil patterns and disposed under the upper electrode layer; and a capacitance layer configured by a lamination comprising a capacitance pattern and a ground pattern, disposed under the lower electrode layer, and overlapping the multiple coil patterns to form an additional capacitance.

### TECHNICAL FIELD

The present disclosure relates to a laminated common mode filter which transmits the current of a signal in a differential mode and removes a noise current in a common mode in an electronic device to which a high speed signal line has been applied.

### BACKGROUND ART

In general, a mobile industry processor interface (MIPI D-PHY) standard is adopted for a mobile terminal as a digital data transmission standard. The MIPI D-PHY standard is a digital data transmission standard in which a main circuit of a mobile terminal and a display or a camera are connected, and is a method of transmitting data as a differential signal using two transmission lines.

As data that are transmitted and received within the mobile terminal are suddenly increased, the mobile terminal requires a transmission method capable of transmitting and receiving data at high speed compared to the MIPI D-PHY.

Accordingly, in the mobile terminal industry, research for applying an MIPI C-PHY standard to the mobile terminal is recently carried out. The MIPI C-PHY standard is a method of transmitting different voltages from the transmission side to three transmission lines, respectively, by using the three transmission lines and differentially outputting differences between the lines by taking the differences on the reception side.

The contents described in the Background Art are to help the understanding of the background of the disclosure, and may include contents that are not a disclosed conventional technology.

### DISCLOSURE

### Technical Problem

The present disclosure has been proposed by considering the aforementioned circumstances, and an object of the present disclosure is to provide a laminated common mode filter which uniformly forms resistance and inductance of coil patterns that constitute each channel while implementing a wide band characteristic.

### Technical Solution

In order to achieve the object, a laminated common mode filter according to an embodiment of the present disclosure includes an upper electrode layer constructed as a stack body including a first coil pattern, a second coil pattern, and a third coil pattern, a lower electrode layer constructed as a stack body including a fourth coil pattern, a fifth coil pattern, and a sixth coil pattern and disposed under the upper electrode layer, and a capacitance layer constructed as a stack body including a capacitance pattern and a ground pattern, disposed under the lower electrode layer, and configured to form additional capacitance by overlapping with the first coil pattern to the sixth coil pattern.

In this case, the upper electrode layer and the lower electrode layer constitute an electrode stack body. The electrode stack body is constructed so that the first coil pattern, the second coil pattern, the third coil pattern, the fourth coil pattern, the fifth coil pattern, and the sixth coil pattern are sequentially stacked. The first coil pattern and the sixth coil pattern form a first coil that constitutes the first channel. The second coil pattern and the third coil pattern are interposed between the first coil pattern and the sixth coil pattern to form a second coil that constitutes a second channel. The fourth coil pattern and the fifth coil pattern are interposed between the third coil pattern and the sixth coil pattern to form a third coil that constitutes a third channel.

The upper electrode layer may include a first sheet configured to have a first terminal pattern and a second terminal pattern disposed to be spaced apart from each other on a first surface thereof, a second sheet configured to have the first coil pattern and a first via hole disposed in a first surface thereof and disposed under the first sheet, a third sheet configured to have the second coil pattern disposed on a first surface thereof and disposed under the second sheet, and a fourth sheet configured to have the third coil pattern disposed on a first surface thereof and disposed under the third sheet.

In this case, the first coil pattern may be disposed on the first surface of the second sheet, interposed between the first sheet and the second sheet, and connected to the sixth coil pattern to form a first channel. A first end of the first coil pattern may be connected to a first end of the first terminal pattern. A second end of the first coil pattern may be disposed to be placed on a line identical with the line of a first side of the second sheet.

The second coil pattern may be disposed on the first surface of the third sheet and interposed between the second sheet and the third sheet. A first end of the second coil pattern may be connected to a first end of the second terminal pattern through the first via hole. A second end of the second coil pattern may be disposed to be placed on a line identical with the line of a second side of the third sheet.

The third coil pattern may be disposed on the first surface of the fourth sheet and interposed between the third sheet and the fourth sheet. A first end of the third coil pattern may be connected to a first end of the second terminal pattern. A second end of the third coil pattern may be disposed to be placed on a line identical with the line of a second side of the fourth sheet.

The first end of the first terminal pattern may be disposed to be adjacent to the center of the first sheet and connected to a first end of the first coil pattern. A second end of the first terminal pattern may be disposed to be placed on a line identical with the line of a first end of the first sheet. A first end of the second terminal pattern may be disposed to be adjacent to the center of the first sheet and connected to a first end of the second coil pattern through the first via hole. A second end of the second terminal pattern may be disposed to be placed on a line identical with the line of the first end of the first sheet.

The lower electrode layer may include a fifth sheet configured to have the fourth coil pattern disposed on a first surface thereof and disposed under the upper electrode layer, a sixth sheet configured to have the fifth coil pattern disposed on a first surface thereof and disposed under the fifth sheet, a seventh sheet configured to have the sixth coil pattern and a second via hole disposed in a first surface thereof and disposed under the sixth sheet, and an eighth sheet configured to have a third terminal pattern and a fourth terminal pattern disposed to be spaced apart from each other on a first surface thereof.

In this case, the fourth coil pattern may be disposed on a first surface of the fifth sheet and interposed between the upper electrode layer and the fifth sheet. A first end of the fourth coil pattern may be disposed to be adjacent to the center of the fifth sheet and connected to a first end of the fifth coil pattern. A second end of the fourth coil pattern may be disposed to be placed on a line identical with the line of a second side of the fifth sheet.

The fifth coil pattern may be disposed on a first surface of the sixth sheet and interposed between the fifth sheet and the sixth sheet. A first end of the fifth coil pattern may be disposed to be adjacent to the center of the sixth sheet, connected to a first end of the fourth coil pattern, and connected to a first end of the third terminal pattern through the second via hole. A second end of the fifth coil pattern may be disposed to be placed on a line identical with the line of a second side of the sixth sheet.

The sixth coil pattern may be disposed on the first surface of the seventh sheet and interposed between the sixth sheet and the seventh sheet. A first end of the sixth coil pattern may be disposed to be adjacent to the center of the sixth sheet, may be connected to a first end of the fourth coil pattern, and may be connected to a first end of the third terminal pattern through the second via hole. A second end of the sixth coil pattern may be disposed to be placed on a line identical with the line of a second side of the seventh sheet.

A first end of the third terminal pattern may be disposed to be adjacent to the center of the eighth sheet and connected to a first end of the fifth coil pattern through the second via hole. A second end of the third terminal pattern may be disposed to be placed on a line identical with the line of a first side of the eighth sheet. A first end of the fourth terminal pattern may be disposed to be adjacent to the center of the eighth sheet and connected to a first end of the sixth coil pattern. A second end of the fourth terminal pattern may be disposed to be placed on a line identical with the line of the first side of the eighth sheet.

In this case, two or less via holes may be formed in each of a plurality of sheets that constitute the upper electrode layer and the lower electrode layer.

The capacitance layer may include a ninth sheet configured to have a ground pattern disposed on a first surface thereof and disposed under the lower electrode layer and a tenth sheet in which the capacitance pattern constructed to form additional capacitance by overlapping with a coil pattern included in an electrode stack body in which the upper electrode layer and the lower electrode layer have been stacked is disposed on a first surface thereof and which is disposed under the ninth sheet.

The ground pattern may include a first ground pattern formed in a plate form, disposed on the first surface of the ninth sheet, and configured to have an outer circumference disposed to be spaced apart from an outer circumference of the ninth sheet, a second ground pattern configured to have a first end connected to the first ground pattern and to have a second end disposed to be placed on a line identical with the line of a third side of the ninth sheet, and a third ground pattern disposed to face the second ground pattern with the first ground pattern interposed therebetween and configured to have a first end connected to the first ground pattern and a second end disposed to be placed on a line identical with the line of a fourth side of the ninth sheet, which faces the third side of the ninth sheet.

The capacitance pattern may include a first capacitance pattern disposed on an upper surface of the tenth sheet, a second capacitance pattern disposed to be spaced apart from the first capacitance pattern on the upper surface of the tenth sheet, and a third capacitance pattern disposed to be spaced apart from the first capacitance pattern and the second capacitance pattern on the upper surface of the tenth sheet. First ends of the first capacitance pattern to the third capacitance pattern may be disposed to be placed on a line identical with the line of one side, among the first side and second side of the tenth sheet.

The capacitance pattern may include a fourth capacitance pattern disposed to face the first capacitance pattern on the upper surface of the tenth sheet, a fifth capacitance pattern spaced apart from the fourth capacitance pattern on the upper surface of the tenth sheet and disposed to face the second capacitance pattern, and a sixth capacitance pattern spaced apart from the fourth capacitance pattern and the fifth capacitance pattern on the upper surface of the tenth sheet and disposed to face the third capacitance pattern. First ends of the fourth capacitance pattern to the sixth capacitance pattern may be disposed to be placed on a line identical with the line of the other side, among the first side and second side of the tenth sheet.

The capacitance layer may be constructed so that a plurality of ground patterns and a plurality of capacitance patterns are alternately stacked.

The upper electrode layer, the lower electrode layer, and the capacitance layer may constitute a filter stack body. The laminated common mode filter according to an embodiment of the present disclosure may include a first external electrode disposed on a second lateral surface of the filter stack body and connected to the first coil pattern and the sixth coil pattern exposed to the second lateral surface of the filter stack body, a second external electrode disposed on the second lateral surface of the filter stack body and connected to the second coil pattern and the third coil pattern exposed to the second lateral surface of the filter stack body, a third external electrode disposed on the second lateral surface of the filter stack body, disposed to face the second external electrode with the first external electrode interposed therebetween, and connected to the fourth coil pattern and the fifth coil pattern exposed to the second lateral surface of the filter stack body, a fourth external electrode disposed on a first lateral surface of the filter stack body, which faces the second lateral surface of the filter stack body, and connected to a first terminal pattern and a fourth terminal pattern exposed to the first lateral surface of the filter stack body, a fifth external electrode disposed on the first lateral surface of the filter stack body and connected to a second terminal pattern exposed to the first lateral surface of the filter stack body, a sixth external electrode disposed on the first lateral surface of the filter stack body, disposed to face the fifth external electrode with the fourth external electrode interposed therebetween, and connected to a third terminal pattern exposed to the first lateral surface of the filter stack body, a seventh external electrode disposed on a third lateral surface of the filter stack body and connected to a first end of the ground pattern, which is exposed to the third lateral surface of the filter stack body, and an eighth external electrode disposed on a fourth lateral surface of the filter stack body, which faces the third lateral surface of the filter stack body, and connected to a second end of the ground pattern, which is exposed to the fourth lateral surface of the filter stack body.

### Advantageous Effects

According to the present disclosure, the laminated common mode filter has an effect in that resistance and inductance of coil patterns that constitute each channel can be uniformly maintained because a distance (interval) between the coil patterns can be made constant.

Furthermore, the laminated common mode filter has an effect in that a change in the inductance characteristic and common mode attenuation characteristic of the coil patterns can be minimized because the terminal patterns for a connection with the external terminal are disposed at the top and bottom of the electrode stack body.

Furthermore, the laminated common mode filter has an effect in that an attenuation band can be expanded because an additional notch is formed in the common mode attenuation characteristic by disposing the capacitance layer under the electrode stack body.

Furthermore, the laminated common mode filter has an effect in that a wide band characteristic can be implemented because an additional pole (i.e., additional capacitance) is formed by the capacitance layer and the coil pattern along with a pole that is formed by the coil patterns of the electrode stack body.

Furthermore, the laminated common mode filter has an effect in that a change in the inductance characteristic of the coil patterns can be minimized by constantly forming a distance (interval) between the channels.

Furthermore, the laminated common mode filter has effects in that magnetic coupling (i.e., electromagnetic coupling) between the first coil to the third coil can be improved and the deterioration of a differential signal can be minimized.

Furthermore, the laminated common mode filter has an effect in that a manufacturing process can be simplified because the electrode stack body can be constructed by stacking sheets in each of which two or less via holes are formed.

That is, in the laminated common mode filter, the number of via holes for connecting the coil patterns can be minimized and two or less via holes are formed in each sheet because the terminal patterns are disposed the top and bottom of the electrode stack body, the second coil pattern and third coil pattern of the second channel are disposed between the first coil pattern and sixth coil pattern of the first channel, and the fourth coil pattern and fifth coil pattern of the third channel are disposed between the third coil pattern and the sixth coil pattern.

### DESCRIPTION OF DRAWINGS

FIG. 1 is a perspective view of a laminated common mode filter according to an embodiment of the present disclosure.

FIG. 2 is a perspective view for describing a filter stack body in FIG. 1.

FIG. 3 is an exploded perspective view for describing an example of an upper electrode layer in FIG. 2.

FIGS. 4 to 7 are diagrams for describing the upper electrode layer in FIG. 3.

FIG. 8 is an exploded perspective view for describing another example of the upper electrode layer in FIG. 2.

FIG. 9 is an exploded perspective view for describing an example of a lower electrode layer in FIG. 2.

FIGS. 10 to 13 are diagrams for describing the lower electrode layer in FIG. 9.

FIG. 14 is an exploded perspective view for describing another example of the upper electrode layer in FIG. 2.

FIGS. 15 to 19 are exploded perspective views for describing a capacitance layer in FIG. 2.

FIG. 20 is a diagram for describing an attenuation characteristic of the laminated common mode filter according to an embodiment of the present disclosure.

FIG. 21 is an exploded perspective view for describing a modified example of the capacitance layer in FIG. 2.

FIG. 22 is a vertical cross-sectional view for describing the filter stack body in FIG. 2.

FIG. 23 is a diagram illustrating an equivalent circuit of the laminated common mode filter according to an embodiment of the present disclosure.

### MODE FOR INVENTION

Hereinafter, preferred embodiments of the present disclosure are described in detail with reference to the accompanying drawings.

Embodiments are provided to explain the present disclosure more fully to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of the embodiments, when it is described that each layer (film), area, pattern, or structure is formed “on” or “under” each substrate, layer (film), area, pad, or pattern, this includes both expressions, including that a layer is formed on another layer “directly” or “with a third layer interposed between the two layers (indirectly)”. Furthermore, a criterion for the term “on or under of each layer” is described based on the drawings.

The drawings are merely for enabling the spirit of the present disclosure to be understood, and it should not be interpreted that the scope of the present disclosure is limited by the drawings. Furthermore, in the drawings, a relative thickness or length or a relative size may be enlarged for convenience and the clarity of description.

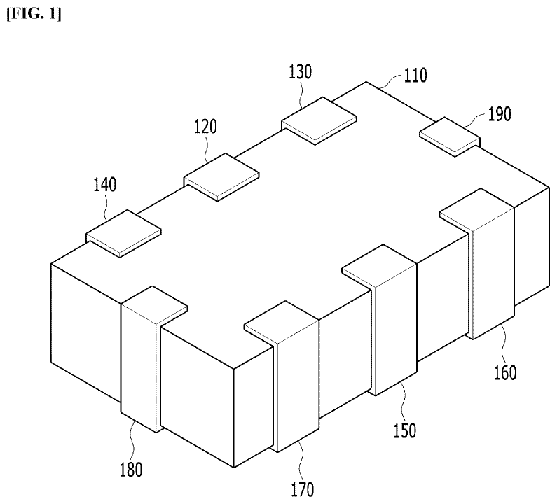

Referring to FIG. 1, a laminated common mode filter according to an embodiment of the present disclosure is constructed to include a filter stack body 110, a first external electrode 120, a second external electrode 130, a third external electrode 140, a fourth external electrode 150, a fifth external electrode 160, a sixth external electrode 170, a seventh external electrode 180, and an eighth external electrode 190.

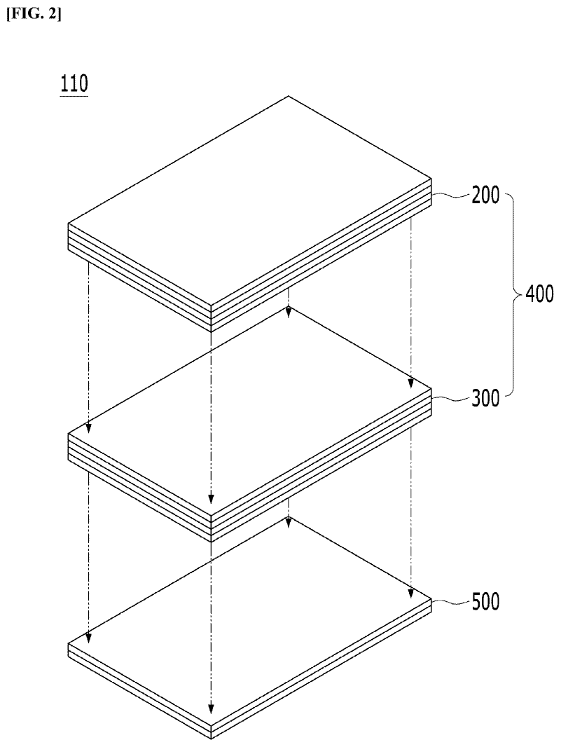

Referring to FIG. 2, the filter stack body 110 is a stack body in which an upper electrode layer 200, a lower electrode layer 300, and a capacitance layer 500 have been stacked.

The upper electrode layer 200 is constructed as a stack body in which a plurality of coil patterns has been formed, and is disposed at the top of the filter stack body 110. In this case, a magnetic layer formed of ferrite, etc. may be further stacked on the upper electrode layer 200.

The upper electrode layer 200 is constructed by stacking a plurality of sheets on each of which a coil pattern has been formed. The coil patterns formed on the plurality of sheets constitute different channels.

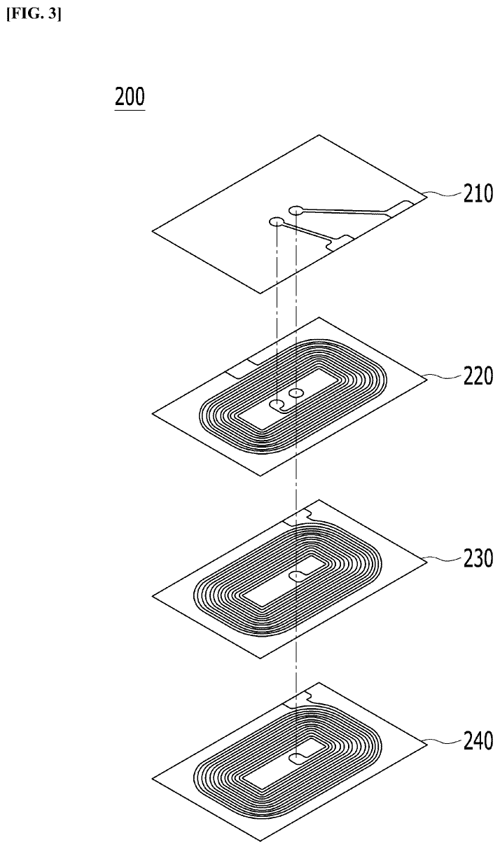

For example, referring to FIG. 3, the upper electrode layer 200 is constructed to include a first sheet 210, a second sheet 220 disposed under the first sheet 210, a third sheet 230 disposed under the second sheet 220, and a fourth sheet 240 disposed under the third sheet 230. In this case, a terminal pattern is formed on the first sheet 210. Coil patterns are formed on the second sheet 220 to the fourth sheet 240.

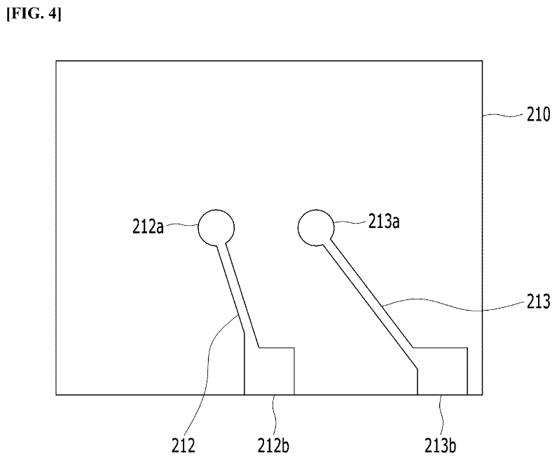

Referring to FIG. 4, a first terminal pattern 212 and a second terminal pattern 213 for connecting the coil patterns of the upper electrode layer 200 to external terminals are disposed in the first sheet 210.

The first terminal pattern 212 is disposed on an upper surface of the first sheet 210. A first end 212a of the first terminal pattern 212 is disposed to be adjacent to the center of the first sheet 210. A second end 212b of the first terminal pattern 212 is disposed to be placed on the same line as a first side of the first sheet 210. Accordingly, the second end 212b of the first terminal pattern 212 is exposed to a first lateral surface of the filter stack body 110.

The second terminal pattern 213 is disposed on the upper surface of the first sheet 210 so that the second terminal pattern 213 is spaced apart from the first terminal pattern 212. A first end 213a of the second terminal pattern 213 is disposed to be adjacent to the center of the first sheet 210. A second end 213b of the second terminal pattern 213 is disposed to be placed on the same line as the first side of the first sheet 210. Accordingly, the second end 213b of the second terminal pattern 213 is exposed to the first lateral surface of the filter stack body 110 in the state in which the second end of the second terminal pattern has been spaced apart from the second end 212b of the first terminal pattern 212.

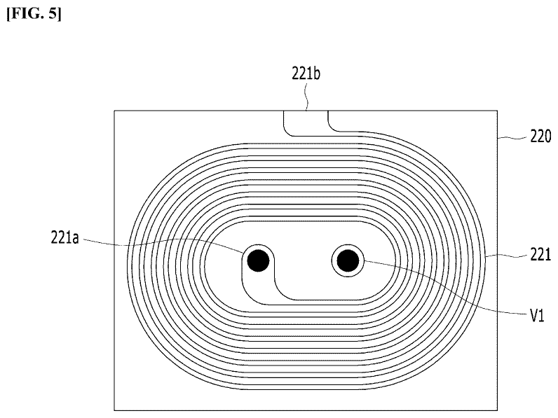

Referring to FIG. 5, the second sheet 220 is disposed under the first sheet 210. A first coil pattern 221 that constitutes a first channel and a first via hole V1 are disposed in the second sheet 220.

The first coil pattern 221 is disposed on an upper surface of the second sheet 220. The first coil pattern 221 forms a first loop that winds the center of the second sheet 220 in plural times. A first end 221a of the first coil pattern 221 is disposed to be adjacent to the center of the second sheet 220. The first end 221a of the first coil pattern 221 is connected to the first end 212a of the first terminal pattern 212 through a via hole. A second end 221b of the first coil pattern 221 is disposed to be placed on the same line as a second side of the second sheet 220. Accordingly, the second end 221b of the first coil pattern 221 is exposed to a second lateral surface of the filter stack body 110. In this case, the second lateral surface of the filter stack body 110 is a lateral surface that faces the first lateral surface of the filter stack body 110.

The first via hole V1 is adjacent to be center of the second sheet 220, and is disposed to be spaced apart from the first end 221a of the first coil pattern 221. The first via hole V1 is formed to penetrate the second sheet 220. An upper part of the first via hole V1 is connected to the second terminal pattern 213. A lower part of the first via hole is connected to a coil pattern that is formed in the third sheet 230 to be described later.

Referring to FIG. 6, the third sheet 230 is disposed under the second sheet 220. A second coil pattern 231 that constitutes a second channel is disposed in the third sheet 230.

The second coil pattern 231 is disposed on an upper surface of the third sheet 230. The second coil pattern 231 forms a second loop that winds the center of the third sheet 230 in plural times. A first end 231a of the second coil pattern 231 is disposed to be adjacent to the center of the third sheet 230. The first end 231a of the second coil pattern 231 is connected to the first end 213a of the second terminal pattern 213 through the first via hole V1 of the second sheet 220. A second end 231b of the second coil pattern 231 is disposed to be placed on the same line as a second side of the third sheet 230. Accordingly, the second end 231b of the second coil pattern 231 is exposed to the second lateral surface of the filter stack body 110.

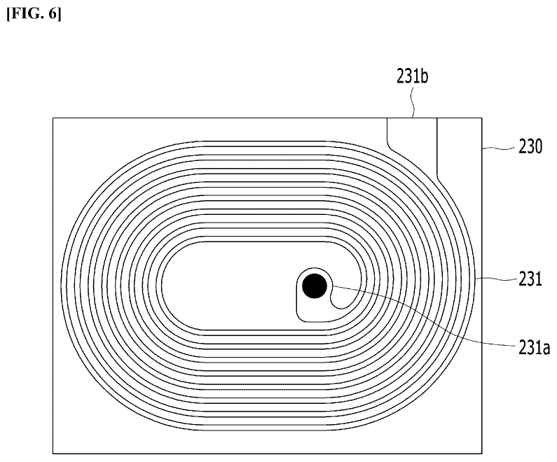

Referring to FIG. 7, the fourth sheet 240 is disposed under the third sheet 230. A third coil pattern 241 that constitutes the second channel along with the second coil pattern 231 is disposed in the fourth sheet 240.

The third coil pattern 241 is disposed on an upper surface of the fourth sheet 240. The third coil pattern 241 forms a third loop that winds the center of the fourth sheet 240 in plural times. A first end 241a of the third coil pattern 241 is disposed to be adjacent to the center of the fourth sheet 240. The first end 241a of the third coil pattern 241 is connected to the first end 231a of the second coil pattern 231 through a via hole. A second end 241b of the third coil pattern 241 is disposed to be placed on the same line as a second side of the fourth sheet 240. Accordingly, the second end of the third coil pattern is exposed to the second lateral surface of the filter stack body 110.

Meanwhile, the coil patterns and the terminal pattern that have been formed in the sheets that constitute the upper electrode layer 200 may be deformed in various forms.

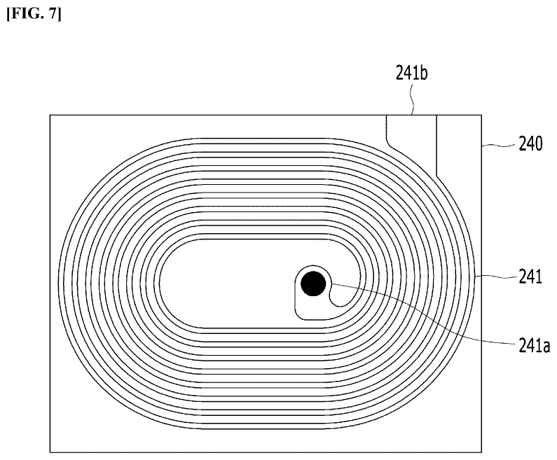

For example, referring to FIG. 8, the first coil pattern 221 to the third coil pattern 241 may each form a loop having a quadrangular shape. The second ends 221b, 231b, and 241b of the first coil pattern 221 to the third coil pattern 241 may each be disposed to be placed on the same line as the first side of each sheet and constructed to be exposed to the first lateral surface of the filter stack body 110. In this case, the second ends 212b and 213b of the first terminal pattern 212 and the second terminal pattern 213 may each be disposed to be placed on the same line as the second side of each sheet and constructed to be exposed to the second lateral surface of the filter stack body 110.

As described above, in the upper electrode layer 200, a shape of the loop that is formed by the coil pattern, a location at which the end of the coil pattern is exposed, etc. may be modified in various forms. However, in the upper electrode layer 200, the sequence in which the first terminal pattern 212, the second terminal pattern 213, the first coil pattern 221, the second coil pattern 231, and the third coil pattern 241 are stacked maintains the sequence illustrated in the drawing.

The lower electrode layer 300 is constructed as a stack body in which a plurality of coil patterns has been formed, and is disposed under the upper electrode layer 200. The lower electrode layer 300 is constructed by stacking a plurality of sheets in which coil patterns have been formed. The coil patterns formed in the plurality of sheets constitute different channels.

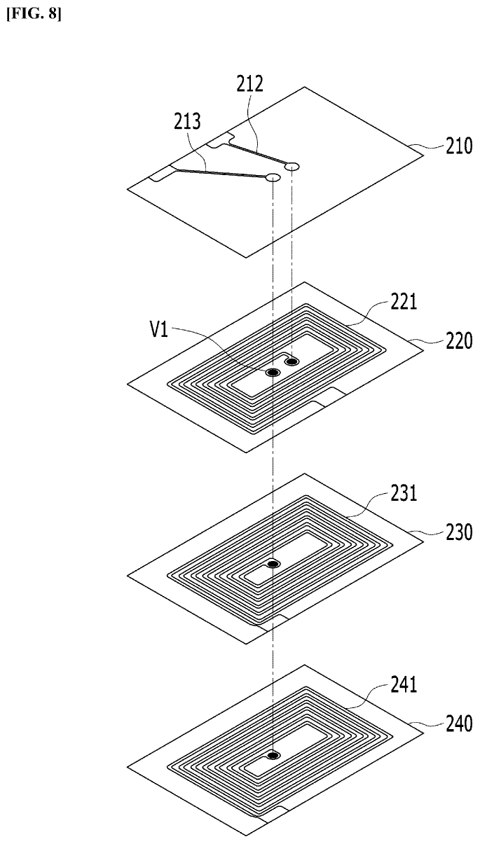

For example, referring to FIG. 9, the lower electrode layer 300 is constructed to include a fifth sheet 310, a sixth sheet 320 disposed under the fifth sheet 310, a seventh sheet 330 disposed under the sixth sheet 320, and an eighth sheet 340 disposed under the seventh sheet 330. In this case, coil patterns are formed in the fifth sheet 310 to the seventh sheet 330, and a terminal pattern is formed in the eighth sheet 340.

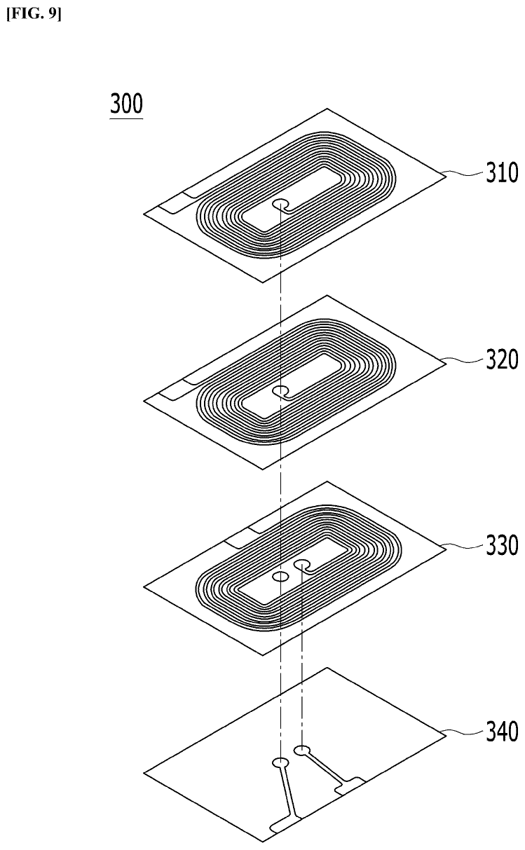

Referring to FIG. 10, the fifth sheet 310 is disposed under the fourth sheet 240. A fourth coil pattern 311 that constitutes a third channel is disposed in the fifth sheet 310.

The fourth coil pattern 311 is disposed on an upper surface of the fifth sheet 310. The fourth coil pattern 311 forms a fourth loop that winds the center of the fifth sheet 310 in plural times. A first end 311a of the fourth coil pattern 311 is disposed to be adjacent to the center of the fifth sheet 310. A second end 311b of the fourth coil pattern 311 is disposed to be placed on the same line as a second side of the fifth sheet 310. Accordingly, the second end 311b of the fourth coil pattern 311 is exposed to the second lateral surface of the filter stack body 110.

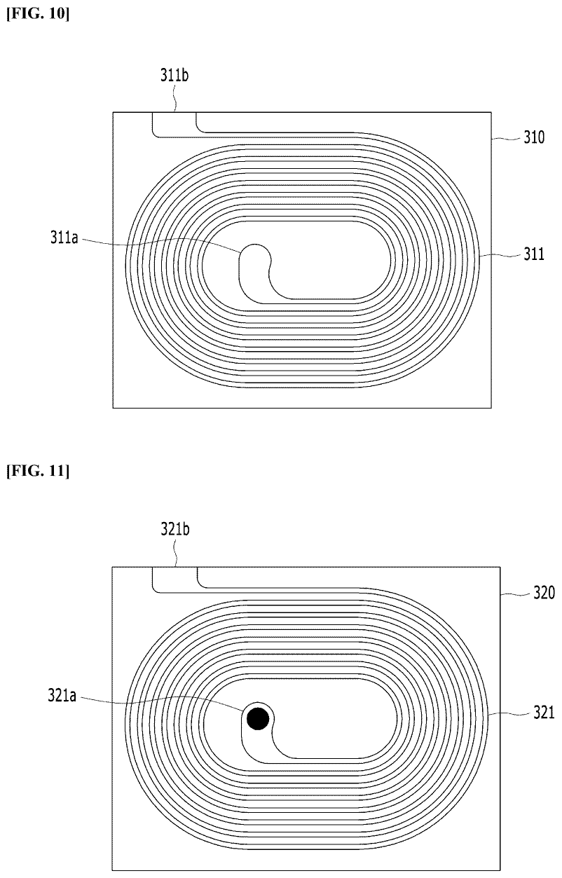

Referring to FIG. 11, the sixth sheet 320 is disposed under the fifth sheet 310. A fifth coil pattern 321 that constitutes the third channel along with the fourth coil pattern 311 is disposed in the sixth sheet 320.

The fifth coil pattern 321 is disposed on an upper surface of the sixth sheet 320. The fifth coil pattern 321 forms a fifth loop that winds the center of the sixth sheet 320 in plural times. A first end 321a of the fifth coil pattern 321 is disposed to be adjacent to the center of the sixth sheet 320. The first end 321a of the fifth coil pattern 321 is connected to the first end 311a of the fourth coil pattern 311 through a via hole. A second end 321b of the fifth coil pattern 321 is disposed to be placed on the same line as the second side of the fifth sheet 310. Accordingly, the second end 321b of the fifth coil pattern 321 is exposed to the second lateral surface of the filter stack body 110.

Referring to FIG. 12, the seventh sheet 330 is disposed under the sixth sheet 320. A sixth coil pattern 331 that constitutes the first channel along with the first coil pattern 221 and a second via hole V2 are disposed in the seventh sheet 330.

The sixth coil pattern 331 is disposed on an upper surface of the seventh sheet 330. The sixth coil pattern 331 forms a sixth loop that winds the center of the seventh sheet 330 in plural times. A first end 331a of the sixth coil pattern 331 is disposed to be adjacent to the center of the seventh sheet 330. A second end 331b of the sixth coil pattern 331 is disposed to be placed on the same line as a second side of the seventh sheet 330. Accordingly, the second end 331b of the sixth coil pattern 331 is exposed to the second lateral surface of the filter stack body 110.

The second via hole V2 is disposed to be adjacent to be center of the seventh sheet 330 and spaced apart from the first end 331a of the sixth coil pattern 331. The second via hole V2 is formed to penetrate the seventh sheet 330. An upper part of the second via hole V2 is connected to the fifth coil pattern 321 and the sixth coil pattern 331. A lower part of the second via hole V2 is connected to the terminal pattern formed in the eighth sheet 340 to be described later.

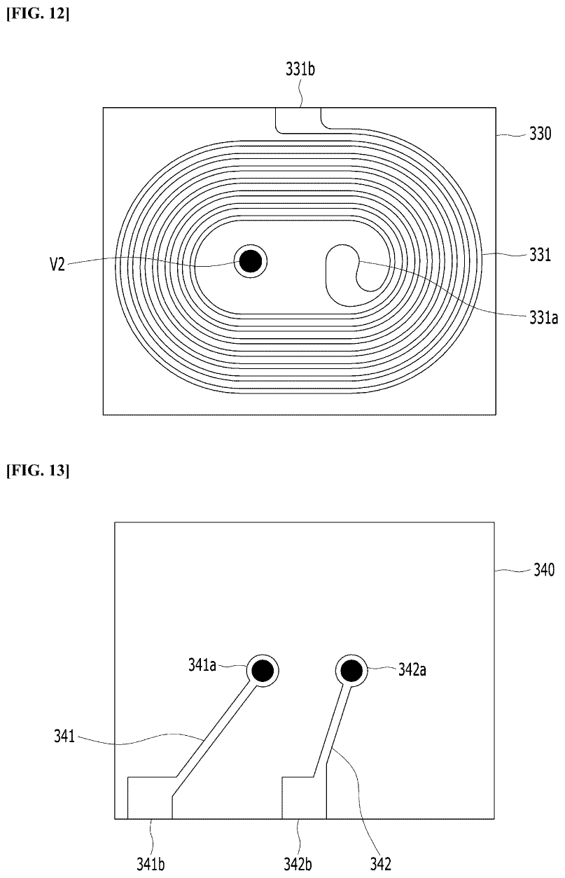

Referring to FIG. 13, a third terminal pattern 341 and a fourth terminal pattern 342 for connecting the coil pattern of the lower electrode layer 300 to an external terminal are disposed in the eighth sheet 340.

The third terminal pattern 341 is disposed on an upper surface of the eighth sheet 340. A first end 341a of the third terminal pattern 341 is disposed to be adjacent to the center of the eighth sheet 340. The first end 341a of the third terminal pattern 341 is connected to the fourth coil pattern 311 and the fifth coil pattern 321 through the second via hole V2. A second end 341b of the third terminal pattern 341 is disposed to be placed on the same line as a first side of the eighth sheet 340. Accordingly, the second end 341b of the third terminal pattern 341 is exposed to the first lateral surface of the filter stack body 110.

The fourth terminal pattern 342 is disposed on the upper surface of the eighth sheet 340 so that the fourth terminal pattern is spaced apart from the third terminal pattern 341. A first end 342a of the fourth terminal pattern 342 is disposed to be adjacent to the center of the eighth sheet 340. The first end 342a of the fourth terminal pattern 342 is connected to the sixth coil pattern 331 through a via hole. A second end 342b of the fourth terminal pattern 342 is disposed to be placed on the same line as the first side of the eighth sheet 340. Accordingly, the second end 342b of the fourth terminal pattern 342 is exposed to the first lateral surface of the filter stack body 110 in the state in which the second end of the fourth terminal pattern has been spaced apart from the second end 341b of the third terminal pattern 341.

Meanwhile, the coil patterns and the terminal pattern that have been formed in the sheets that constitute the lower electrode layer 300 may be deformed in various forms.

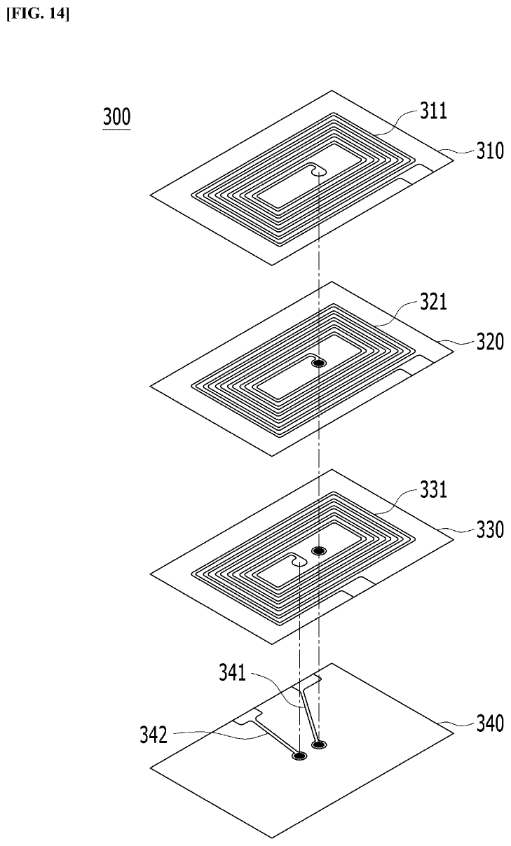

For example, referring to FIG. 14, the fourth coil pattern 311 to the sixth coil pattern 331 may form a loop having a quadrangular shape. The second ends 311b, 321b, and 331b of the fourth coil pattern 311 to the sixth coil pattern 331 may each be disposed to be placed on the same line as the first side of each sheet, and may be constructed to be exposed to the first lateral surface of the filter stack body 110. In this case, the second ends 341b and 342b of the third terminal pattern 341 and the fourth terminal pattern 342 may each be disposed to be placed on the same line as the second side of each sheet, and may be constructed to be exposed the second lateral surface of the filter stack body 110. As described above, in the lower electrode layer 300, a shape of the loop that is formed by the coil pattern, a location at which the end of the coil pattern is exposed, etc. may be modified in various forms. However, in the lower electrode layer 300, the sequence in which the fourth coil pattern 311, the fifth coil pattern 321, the sixth coil pattern 331, the third terminal pattern 341, and the fourth terminal pattern 342 are stacked maintains the sequence illustrated in the drawing.

The upper electrode layer 200 and the lower electrode layer 300 constitute an electrode stack body 400. The electrode stack body 400 is constructed so that the first coil pattern 221, the second coil pattern 231, the third coil pattern 241, the fourth coil pattern 311, the fifth coil pattern 321, and the sixth coil pattern 331 are sequentially stacked. In this case, the first coil pattern 221 and the sixth coil pattern 331 form a first coil that constitutes the first channel. The second coil pattern 231 and the third coil pattern 241 form a second coil that constitutes the second channel. The fourth coil pattern 311 and the fifth coil pattern 321 form a third coil that constitutes the third channel.

Accordingly, the coil pattern of the first channel, the coil pattern of the second channel, the coil pattern of the second channel, the coil pattern of the third channel, the coil pattern of the third channel, and the coil pattern of the first channel are sequentially disposed in the electrode stack body 400.

Accordingly, the laminated common mode filter according to an embodiment of the present disclosure can uniformly maintain resistance and inductance of coil patterns that constitute each channel because a distance (interval) between the coil patterns that constitute each channel can be made constant.

Furthermore, the laminated common mode filter according to an embodiment of the present disclosure can minimize a change in the inductance characteristic and common mode attenuation characteristic of the coil patterns because the terminal patterns for a connection with the external terminal are disposed at the top and bottom of the electrode stack body 400. In this case, if the terminal pattern is disposed at any one place of the top and bottom, the common mode attenuation characteristic is changed because an inductance characteristic of each channel is changed or an inductance characteristic of each coil pattern is changed.

Meanwhile, the laminated common mode filter according to an embodiment of the present disclosure can minimize the number of via holes for connecting the coil patterns because the terminal patterns 212, 213, 341, and 342 are disposed at the top and bottom of the electrode stack body 400, the second coil pattern 231 and third coil pattern 241 of the second channel are disposed between the first coil pattern 221 and sixth coil pattern 331 of the first channel, and the fourth coil pattern 311 and fifth coil pattern 321 of the third channel are disposed between the third coil pattern 241 and the sixth coil pattern 331. In this case, in the laminated common mode filter according to an embodiment of the present disclosure, two or less via holes are formed in each sheet.

The capacitance layer 500 is constructed as a stack body in which a ground pattern and a plurality of capacitance patterns have been formed, and is disposed under the lower electrode layer 300. In this case, the capacitance layer 500 may be stacked under the lower electrode layer 300 in the state in which a magnetic layer formed of ferrite, etc. has been interposed between the capacitance layer and the lower electrode layer 300. A magnetic layer formed of ferrite, etc. may also be stacked on a lower part of the capacitance layer 500.

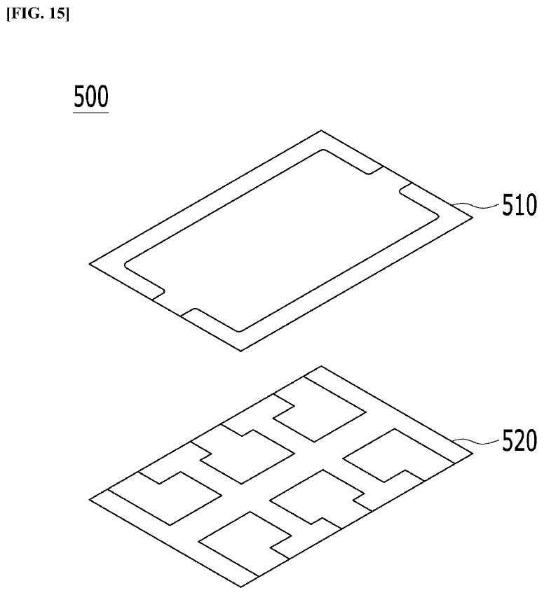

For example, referring to FIG. 15, the capacitance layer 500 is constructed to include a ninth sheet 510 and a tenth sheet 520 disposed under the ninth sheet 510.

The ninth sheet 510 is disposed under the eighth sheet 340. A ground pattern is disposed in the ninth sheet 510.

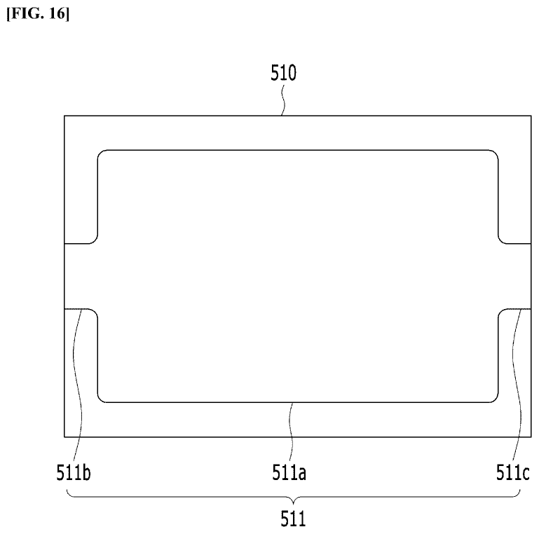

Referring to FIG. 16, a ground pattern 511 is disposed on an upper surface of the ninth sheet 510. The ground pattern 511 may be constructed to include a first ground pattern 511a, a second ground pattern 511b, and a third ground pattern 511c.

The first ground pattern 511a is formed in a plate form, disposed at the center of the upper surface of the ninth sheet 510, and disposed to have an outer circumference spaced apart from four sides of the ninth sheet 510.

The second ground pattern 511b is extended from a third side of the first ground pattern 511a and disposed to be placed on the same line as a third side of the ninth sheet 510. That is, a first end of the second ground pattern 511b is connected to the third side of the first ground pattern 511a. A second end of the second ground pattern 511b is disposed to be placed on the same line as the third side of the ninth sheet 510.

The third ground pattern 511c is extended from a fourth side of the first ground pattern 511a and disposed to be placed on the same line as a fourth side of the ninth sheet 510. That is, a first end of the third ground pattern 511c is connected to the fourth side of the first ground pattern 511a. A second end of the third ground pattern 511c is disposed to be placed on the same line as the fourth side of the ninth sheet 510.

Accordingly, the ground pattern 511 is exposed to a third lateral surface and fourth lateral surface of the filter stack body 110.

The tenth sheet 520 is disposed under the ninth sheet 510. A capacitance pattern is disposed on an upper surface of the tenth sheet 520.

The capacitance pattern is disposed to overlap the coil pattern included in the electrode stack body 400. The capacitance pattern forms capacitance along with the coil pattern. Accordingly, the capacitance pattern forms an additional notch in the common mode attenuation characteristic so that an attenuation band is expanded and the laminated common mode filter has a wide band characteristic having an attenuation band between approximately 1 GHz and 10 GHz.

The capacitance pattern may be composed of a plurality of patterns disposed at an input stage of the laminated common mode filter.

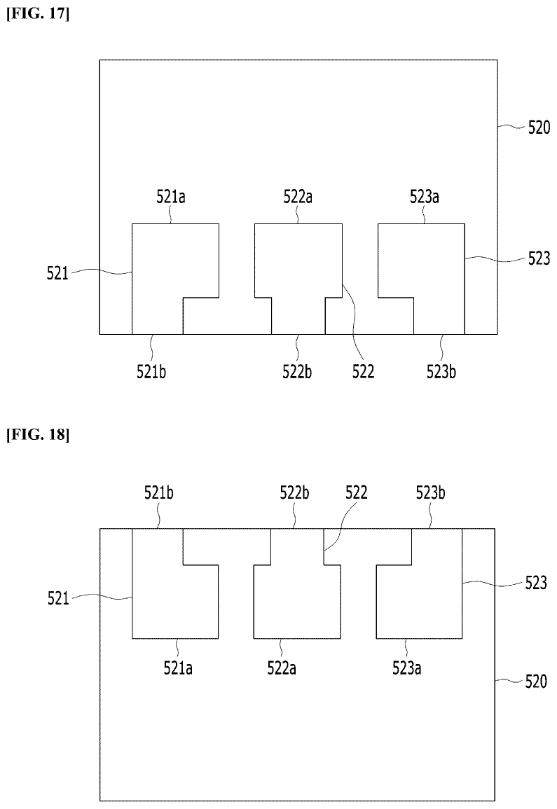

For example, referring to FIG. 17, the capacitance pattern may be constructed to include a first capacitance pattern 521, a second capacitance pattern 522, and a third capacitance pattern 523. In this case, the first capacitance pattern 521 to the third capacitance pattern 523 are disposed at the input stage (i.e., the first lateral surface of the filter stack body 110) of the laminated common mode filter.

The first capacitance pattern 521 is disposed on the upper surface of the tenth sheet 520. A first end 521a of the first capacitance pattern 521 is disposed to be adjacent to the center of the tenth sheet 520. A second end 521b of the first capacitance pattern 521 is disposed to be placed on the same line as a first side of the tenth sheet 520. Accordingly, the first capacitance pattern 521 is exposed to the first lateral surface of the filter stack body 110.

The second capacitance pattern 522 is disposed on the upper surface of the tenth sheet 520 so that the second capacitance pattern is spaced apart from the first capacitance pattern 521. A first end 522a of the second capacitance pattern 522 is disposed to be adjacent to the center of the tenth sheet 520. A second end 522b of the second capacitance pattern 522 is disposed to be placed on the same line as the first side of the tenth sheet 520. Accordingly, the second capacitance pattern 522 is exposed to the first lateral surface of the filter stack body 110.

The third capacitance pattern 523 is disposed on the upper surface of the tenth sheet 520. The third capacitance pattern 523 is spaced apart from the first capacitance pattern 521 and the second capacitance pattern 522, and is disposed to face the first capacitance pattern 521 with the second capacitance pattern 522 interposed therebetween.

A first end 523a of the third capacitance pattern 523 is disposed to be adjacent to the center of the tenth sheet 520. A second end 523b of the third capacitance pattern 523 is disposed to be placed on the same line as the first side of the tenth sheet 520. Accordingly, the third capacitance pattern 523 is exposed to the first lateral surface of the filter stack body 110.

The capacitance pattern may be composed of a plurality of patterns disposed at an output stage of the laminated common mode filter.

For example, referring to FIG. 18, the first capacitance pattern 521 to the third capacitance pattern 523 are disposed at the output stage (i.e., the second lateral surface of the filter stack body 110) of the laminated common mode filter. That is, the first capacitance pattern 521, the second capacitance pattern 522, and the third capacitance pattern 523 are disposed to be exposed to the second lateral surface of the filter stack body 110.

The first ends 521a, 522a, and 523a of the first capacitance pattern 521, the second capacitance pattern 522, and the third capacitance pattern 523 are disposed to be adjacent to the center of the tenth sheet 520. The second ends 521b, 522b, and 523b of the first capacitance pattern 521, the second capacitance pattern 522, and the third capacitance pattern 523 are disposed to be placed on the same line as a second side of the tenth sheet 520. Accordingly, the first capacitance pattern 521, the second capacitance pattern 522, and the third capacitance pattern 523 are exposed to the second lateral surface of the filter stack body 110.

The capacitance pattern may be composed of a plurality of patterns disposed at the input stage and output stage of the laminated common mode filter.

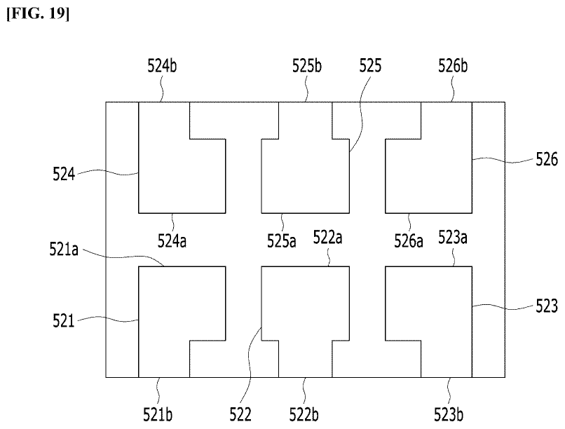

For example, referring to FIG. 19, the capacitance pattern is constructed to include a first capacitance pattern 521, a second capacitance pattern 522, a third capacitance pattern 523, a fourth capacitance pattern 524, a fifth capacitance pattern 525, and a sixth capacitance pattern 526. In this case, the first capacitance pattern 521 to the third capacitance pattern 523 are disposed at the input stage (i.e., the first lateral surface of the filter stack body 110) of the laminated common mode filter. The fourth capacitance pattern 524 to the sixth capacitance pattern 526 are disposed at the output stage (i.e., the second lateral surface of the filter stack body 110) of the laminated common mode filter.

The first capacitance pattern 521 is disposed on the upper surface of the tenth sheet 520. A first end 521a of the first capacitance pattern 521 is disposed to be adjacent to the center of the tenth sheet 520. A second end 521b of the first capacitance pattern 521 is disposed to be placed on the same line as the first side of the tenth sheet 520. Accordingly, the first capacitance pattern 521 is exposed to the first lateral surface of the filter stack body 110.

The second capacitance pattern 522 is disposed on upper surface of the tenth sheet 520 so that the second capacitance pattern is spaced apart from the first capacitance pattern 521. A first end 522a of the second capacitance pattern 522 is disposed to be adjacent to the center of the tenth sheet 520. A second end 522b of the second capacitance pattern 522 is disposed to be placed on the same line as the first side of the tenth sheet 520. Accordingly, the second capacitance pattern 522 is exposed to the first lateral surface of the filter stack body 110.

The third capacitance pattern 523 is disposed on the upper surface of the tenth sheet 520. The third capacitance pattern 523 is spaced apart from the first capacitance pattern 521 and the second capacitance pattern 522, and is disposed to face the first capacitance pattern 521 with the second capacitance pattern 522 interposed therebetween.

A first end 523a of the third capacitance pattern 523 is disposed to be adjacent to the center of the tenth sheet 520. A second end 523b of the third capacitance pattern 523 is disposed to be placed on the same line as the first side of the tenth sheet 520. Accordingly, the third capacitance pattern 523 is exposed to the first lateral surface of the filter stack body 110.

The fourth capacitance pattern 524 is disposed to face the first capacitance pattern 521 on the upper surface of the tenth sheet 520. A first end 524a of the fourth capacitance pattern 524 is disposed to be adjacent to the center of the tenth sheet 520. A second end 524b of the fourth capacitance pattern 524 is disposed to be placed on the same line as the second side of the tenth sheet 520. Accordingly, the fourth capacitance pattern 524 is exposed to the second lateral surface of the filter stack body 110.

The fifth capacitance pattern 525 is disposed on the upper surface of the tenth sheet 520 so that the fifth capacitance pattern is spaced apart from the fourth capacitance pattern 524. The fifth capacitance pattern 525 is disposed to face the second capacitance pattern 522. A first end 525a of the fifth capacitance pattern 525 is disposed to be adjacent to the center of the tenth sheet 520. A second end 525b of the fifth capacitance pattern 525 is disposed to be placed on the same line as the second side of the tenth sheet 520. Accordingly, the fifth capacitance pattern 525 is exposed to the second lateral surface of the filter stack body 110.

The sixth capacitance pattern 526 is disposed to face the third capacitance pattern 523 on the upper surface of the tenth sheet 520. The sixth capacitance pattern 526 is spaced apart from the fourth capacitance pattern 524 and the fifth capacitance pattern 525, and is disposed to face the fourth capacitance pattern 524 with the fifth capacitance pattern 525 interposed therebetween.

A first end 526a of the sixth capacitance pattern 526 is disposed to be adjacent to the center of the tenth sheet 520. A second end 526b of the sixth capacitance pattern 526 is disposed to be placed on the same line as the second side of the tenth sheet 520. Accordingly, the sixth capacitance pattern 526 is exposed to the second lateral surface of the filter stack body 110.

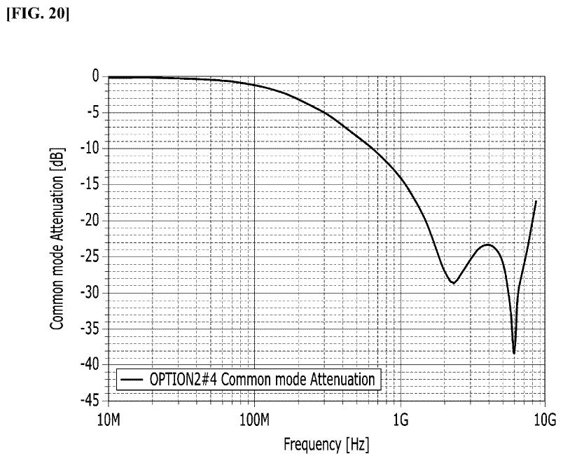

Referring to FIG. 20, the capacitance layer 500 is composed of the ground pattern 511 and the capacitance pattern and disposed under the electrode stack body 400, and forms capacitance along with the coil pattern of the electrode stack body 400. Accordingly, the laminated common mode filter can expand an attenuation band by forming an additional notch in the common mode attenuation characteristic.

That is, the laminated common mode filter can implement a wide band characteristic by forming an additional pole attributable to the capacitance layer 500 and the coil pattern along with a pole that is formed by the coil patterns of the electrode stack body 400.

Meanwhile, the capacitance layer 500 may be constructed to include a plurality of ground patterns and a plurality of capacitance patterns for adjusting the location of the additional pole.

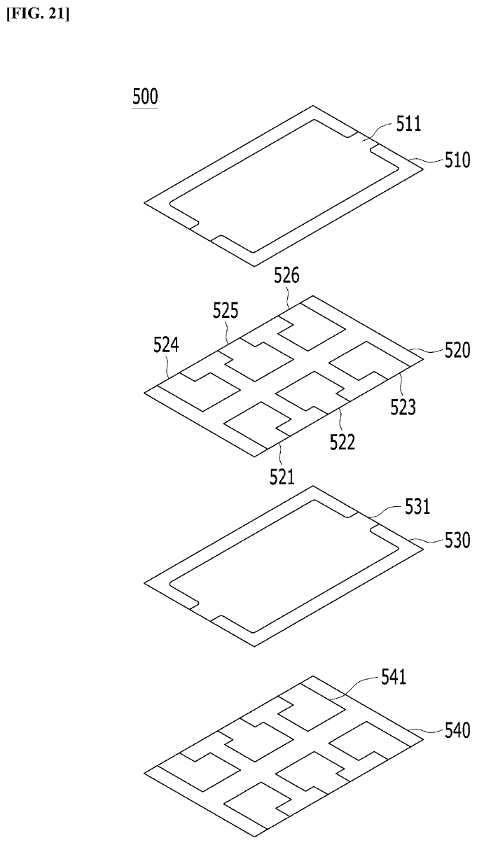

For example, referring to FIG. 21, the capacitance layer 500 may be constructed to further include an eleventh sheet 530 in which a ground pattern 531 is disposed and a twelfth sheet 540 in which a plurality of capacitance patterns 541 is disposed. In this case, the number of ground patterns 531 and the number of capacitance patterns 541 that are added may be different because the location of an additional pole in the laminated common mode filter is adjusted by capacitance.

The first external electrode 120 is disposed on the second lateral surface of the filter stack body 110. The first external electrode 120 is connected to the second end 221b of the first coil pattern 221 and the second end 331b of the sixth coil pattern 331. Both ends of the first external electrode 120 may be formed to extend to an upper surface and lower surface of the filter stack body 110.

The second external electrode 130 is disposed on the second lateral surface of the filter stack body 110. The second external electrode 130 is disposed to be adjacent to the fourth lateral surface of the filter stack body 110, and is connected to the second end 231b of the second coil pattern 231 and the second end 241b of the third coil pattern 241. Both ends of the second external electrode 130 may be formed to extend to the upper surface and lower surface of the filter stack body 110.

The third external electrode 140 is disposed on the second lateral surface of the filter stack body 110. The third external electrode 140 is disposed to be adjacent to the third lateral surface of the filter stack body 110, and is connected to the second end 311b of the fourth coil pattern 311 and the second end 321b of the fifth coil pattern 321. Both ends of the third external electrode 140 may be formed to extend to the upper surface and lower surface of the filter stack body 110.

The fourth external electrode 150 is disposed on the first lateral surface of the filter stack body 110. The fourth external electrode 150 is connected to the second end 212b of the first terminal pattern 212 and the second end 342b of the fourth terminal pattern 342. Both ends of the fourth external electrode 150 may be formed to extend to the upper surface and lower surface of the filter stack body 110.

The fifth external electrode 160 is disposed on the first lateral surface of the filter stack body 110. The fifth external electrode 160 is disposed to be adjacent to the fourth lateral surface of the filter stack body 110 and connected to the second end 213b of the second terminal pattern 213. Both ends of the fifth external electrode 160 may be formed to extend to the upper surface and lower surface of the filter stack body 110. The sixth external electrode 170 is disposed on the first lateral surface of the filter stack body 110. The sixth external electrode 170 is disposed to be adjacent to the third lateral surface of the filter stack body 110 and connected to the second end 341b of the third terminal pattern 341. Both ends of the sixth external electrode 170 may be formed to extend to the upper surface and lower surface of the filter stack body 110.

The seventh external electrode 180 is disposed on the third lateral surface of the filter stack body 110. The seventh external electrode 180 is connected to a first end of the ground pattern 511. Both ends of the seventh external electrode 180 may be formed to extend to the upper surface and lower surface of the filter stack body 110.

The eighth external electrode 190 is disposed on the fourth lateral surface of the filter stack body 110. The eighth external electrode 190 is connected to a second end of the ground pattern 511. Both ends of the eighth external electrode 190 may be formed to extend to the upper surface and lower surface of the filter stack body 110.

The first external electrode 120 and the fourth external electrode 150 operate as an input and output of the first channel that is constructed by the first coil pattern 221 and the sixth coil pattern 331. The second external electrode 130 and the fifth external electrode 160 operate as an input and output of the second channel that is constructed by the second coil pattern 231 and the third coil pattern 241. The third external electrode 140 and the sixth external electrode 170 operate as an input and output of the third channel that is constructed by the fourth coil pattern 311 and the fifth coil pattern 321.

Referring to FIG. 22, the laminated common mode filter according to an embodiment of the present disclosure is constructed to include six coil patterns that constitute three channels. The first coil pattern 221 and the sixth coil pattern 331 constitute the first channel, and are disposed at an upper part and lower part of the electrode stack body 400. The second coil pattern 231 and the third coil pattern 241 are stacked in parallel to constitute the second channel, and are disposed between the first coil pattern 221 and the sixth coil pattern 331. The fourth coil pattern 311 and the fifth coil pattern 321 are stacked in parallel to constitute the third channel, and are disposed between the third coil pattern 241 and the sixth coil pattern 331. Accordingly, the laminated common mode filter can minimize a change in the inductance characteristic of the coil patterns because a distance (interval) between the channels is constantly constructed.

Furthermore, the laminated common mode filter can uniformly form resistance and inductance of the coil patterns that constitute each channel because the terminal patterns that connect the coil patterns to the external electrode are disposed at the top and bottom of the electrode stack body 400 and a distance between the coil pattern and the terminal pattern can be identically constructed for each channel.

The laminated common mode filter according to an embodiment of the present disclosure can improve magnetic coupling (i.e., electromagnetic coupling) between the first coil to the third coil and minimize the deterioration of a differential signal.

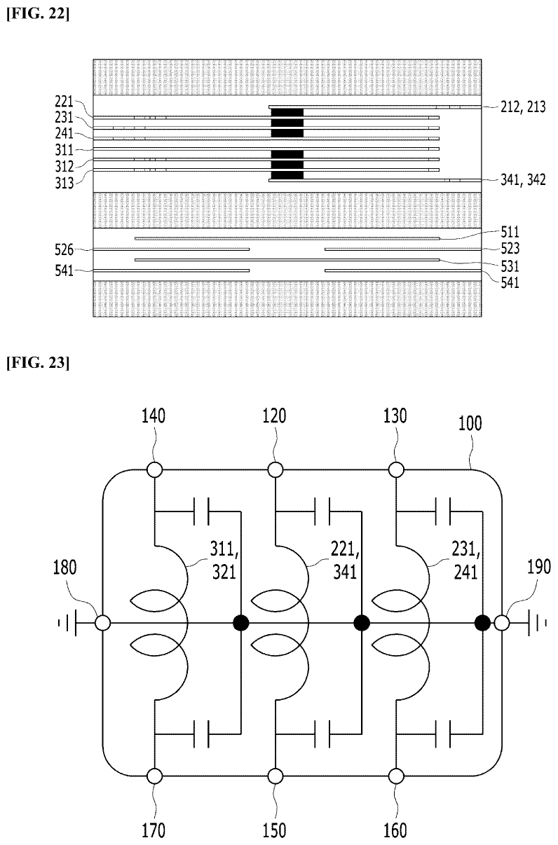

Referring to FIG. 23, in the laminated common mode filter according to an embodiment of the present disclosure, capacitance is formed between the first coil and the second coil, between the second coil and the third coil, and between the first coil and the third coil.

In this case, a coupling effect is generated between the coil and the capacitance pattern because the capacitance layer 500 is disposed under the electrode stack body 400 composed of the upper electrode layer 200 and the lower electrode layer 300. Accordingly, capacitance between the coil and the capacitance pattern is additionally formed.

As described above, the laminated common mode filter according to an embodiment of the present disclosure can increase capacitance without adding an electrode layer composed of a sheet layer in which a coil pattern has been formed because additional capacitance is formed between each coil and the capacitance pattern.

Furthermore, the laminated common mode filter according to an embodiment of the present disclosure can expand an attenuation band by forming an additional notch in the common mode attenuation characteristic because additional capacitance is formed between the coil and the capacitance pattern.

The above description is merely a description of the technical spirit of the present disclosure, and those skilled in the art may change and modify the present disclosure in various ways without departing from the essential characteristic of the present disclosure. Accordingly, the embodiments described in the present disclosure should not be construed as limiting the technical spirit of the present disclosure, but should be construed as describing the technical spirit of the present disclosure. The technical spirit of the present disclosure is not restricted by the embodiments. The range of protection of the present disclosure should be construed based on the following claims, and all of technical spirits within an equivalent range of the present disclosure should be construed as being included in the scope of rights of the present disclosure.

1. A laminated common mode filter comprising:
an upper electrode layer constructed as a stack body comprising a first coil pattern, a second coil pattern, and a third coil pattern;
a lower electrode layer constructed as a stack body comprising a fourth coil pattern, a fifth coil pattern, and a sixth coil pattern and disposed under the upper electrode layer; and
a capacitance layer constructed as a stack body comprising a capacitance pattern and a ground pattern, disposed under the lower electrode layer, and configured to form additional capacitance by overlapping with the first coil pattern to the sixth coil pattern.

2. The laminated common mode filter of claim 1, wherein:
the upper electrode layer and the lower electrode layer constitute an electrode stack body,
the electrode stack body is constructed so that the first coil pattern, the second coil pattern, the third coil pattern, the fourth coil pattern, the fifth coil pattern, and the sixth coil pattern are sequentially stacked,
the first coil pattern and the sixth coil pattern form a first coil that constitutes the first channel,
the second coil pattern and the third coil pattern are interposed between the first coil pattern and the sixth coil pattern to form a second coil that constitutes a second channel, and
the fourth coil pattern and the fifth coil pattern are interposed between the third coil pattern and the sixth coil pattern to form a third coil that constitutes a third channel.

3. The laminated common mode filter of claim 1, wherein the upper electrode layer comprises:
a first sheet configured to have a first terminal pattern and a second terminal pattern disposed to be spaced apart from each other on a first surface thereof;
a second sheet configured to have the first coil pattern and a first via hole disposed in a first surface thereof and disposed under the first sheet;
a third sheet configured to have the second coil pattern disposed on a first surface thereof and disposed under the second sheet; and
a fourth sheet configured to have the third coil pattern disposed on a first surface thereof and disposed under the third sheet.

4. The laminated common mode filter of claim 3, wherein:
the first coil pattern is disposed on the first surface of the second sheet, interposed between the first sheet and the second sheet, and connected to the sixth coil pattern to form a first channel, and
a first end of the first coil pattern is connected to a first end of the first terminal pattern, and
a second end of the first coil pattern is disposed to be placed on a line identical with a line of a first side of the second sheet.

5. The laminated common mode filter of claim 3, wherein:
the second coil pattern is disposed on the first surface of the third sheet and interposed between the second sheet and the third sheet,
a first end of the second coil pattern is connected to a first end of the second terminal pattern through the first via hole, and
a second end of the second coil pattern is disposed to be placed on a line identical with a line of a second side of the third sheet.

6. The laminated common mode filter of claim 3, wherein:
the third coil pattern is disposed on the first surface of the fourth sheet and interposed between the third sheet and the fourth sheet,
a first end of the third coil pattern is connected to a first end of the second terminal pattern, and
a second end of the third coil pattern is disposed to be placed on a line identical with a line of a second side of the fourth sheet.

7. The laminated common mode filter of claim 3, wherein:
the first end of the first terminal pattern is disposed to be adjacent to a center of the first sheet and connected to a first end of the first coil pattern, and a second end of the first terminal pattern is disposed to be placed on a line identical with a line of a first end of the first sheet, and
a first end of the second terminal pattern is disposed to be adjacent to the center of the first sheet and connected to a first end of the second coil pattern through the first via hole, and a second end of the second terminal pattern is disposed to be placed on a line identical with a line of the first end of the first sheet.

8. The laminated common mode filter of claim 1, wherein the lower electrode layer comprises:
a fifth sheet configured to have the fourth coil pattern disposed on a first surface thereof and disposed under the upper electrode layer;
a sixth sheet configured to have the fifth coil pattern disposed on a first surface thereof and disposed under the fifth sheet;
a seventh sheet configured to have the sixth coil pattern and a second via hole disposed in a first surface thereof and disposed under the sixth sheet; and
an eighth sheet configured to have a third terminal pattern and a fourth terminal pattern disposed to be spaced apart from each other on a first surface thereof.

9. The laminated common mode filter of claim 8, wherein:
the fourth coil pattern is disposed on a first surface of the fifth sheet and interposed between the upper electrode layer and the fifth sheet,
a first end of the fourth coil pattern is disposed to be adjacent to a center of the fifth sheet and connected to a first end of the fifth coil pattern, and
a second end of the fourth coil pattern is disposed to be placed on a line identical with a line of a second side of the fifth sheet.

10. The laminated common mode filter of claim 8, wherein:
the fifth coil pattern is disposed on a first surface of the sixth sheet and interposed between the fifth sheet and the sixth sheet,
a first end of the fifth coil pattern is disposed to be adjacent to a center of the sixth sheet, connected to a first end of the fourth coil pattern, and connected to a first end of the third terminal pattern through the second via hole, and
a second end of the fifth coil pattern is disposed to be placed on a line identical with a line of a second side of the sixth sheet.

11. The laminated common mode filter of claim 8, wherein:
the sixth coil pattern is disposed on the first surface of the seventh sheet and interposed between the sixth sheet and the seventh sheet,
a first end of the sixth coil pattern is disposed to be adjacent to a center of the sixth sheet, connected to a first end of the fourth coil pattern, and connected to a first end of the third terminal pattern through the second via hole, and
a second end of the sixth coil pattern is disposed to be placed on a line identical with a line of a second side of the seventh sheet.

12. The laminated common mode filter of claim 8, wherein:
a first end of the third terminal pattern is disposed to be adjacent to a center of the eighth sheet and connected to a first end of the fifth coil pattern through the second via hole, and a second end of the third terminal pattern is disposed to be placed on a line identical with a line of a first side of the eighth sheet, and
a first end of the fourth terminal pattern is disposed to be adjacent to the center of the eighth sheet and connected to a first end of the sixth coil pattern, and a second end of the fourth terminal pattern is disposed to be placed on a line identical with a line of the first side of the eighth sheet.

13. The laminated common mode filter of claim 1, wherein two or less via holes are formed in each of a plurality of sheets that constitute the upper electrode layer and the lower electrode layer.

14. The laminated common mode filter of claim 1, wherein the capacitance layer comprises:
a ninth sheet configured to have a ground pattern disposed on a first surface thereof and disposed under the lower electrode layer; and
a tenth sheet in which the capacitance pattern constructed to form additional capacitance by overlapping with a coil pattern included in an electrode stack body in which the upper electrode layer and the lower electrode layer have been stacked is disposed on a first surface thereof and which is disposed under the ninth sheet.

15. The laminated common mode filter of claim 14, wherein the ground pattern comprises:
a first ground pattern formed in a plate form, disposed on the first surface of the ninth sheet, and configured to have an outer circumference disposed to be spaced apart from an outer circumference of the ninth sheet;
a second ground pattern configured to have a first end connected to the first ground pattern and to have a second end disposed to be placed on a line identical with a line of a third side of the ninth sheet; and
a third ground pattern disposed to face the second ground pattern with the first ground pattern interposed therebetween and configured to have a first end connected to the first ground pattern and a second end disposed to be placed on a line identical with a line of a fourth side of the ninth sheet, which faces the third side of the ninth sheet.

16. The laminated common mode filter of claim 14, wherein the capacitance pattern comprises:
a first capacitance pattern disposed on an upper surface of the tenth sheet;
a second capacitance pattern disposed to be spaced apart from the first capacitance pattern on the upper surface of the tenth sheet; and
a third capacitance pattern disposed to be spaced apart from the first capacitance pattern and the second capacitance pattern on the upper surface of the tenth sheet,
wherein first ends of the first capacitance pattern to the third capacitance pattern are disposed to be placed on a line identical with a line of one side, among the first side and second side of the tenth sheet.

17. The laminated common mode filter of claim 16, wherein the capacitance pattern comprises:
a fourth capacitance pattern disposed to face the first capacitance pattern on the upper surface of the tenth sheet;
a fifth capacitance pattern spaced apart from the fourth capacitance pattern on the upper surface of the tenth sheet and disposed to face the second capacitance pattern; and
a sixth capacitance pattern spaced apart from the fourth capacitance pattern and the fifth capacitance pattern on the upper surface of the tenth sheet and disposed to face the third capacitance pattern,
wherein first ends of the fourth capacitance pattern to the sixth capacitance pattern are disposed to be placed on a line identical with a line of the other side, among the first side and second side of the tenth sheet.

18. The laminated common mode filter of claim 14, wherein the capacitance layer is constructed so that a plurality of ground patterns and a plurality of capacitance patterns are alternately stacked.

19. The laminated common mode filter of claim 1, wherein:
the upper electrode layer, the lower electrode layer, and the capacitance layer constitute a filter stack body, and
the laminated common mode filter further comprises:
a first external electrode disposed on a second lateral surface of the filter stack body and connected to the first coil pattern and the sixth coil pattern exposed to the second lateral surface of the filter stack body;
a second external electrode disposed on the second lateral surface of the filter stack body and connected to the second coil pattern and the third coil pattern exposed to the second lateral surface of the filter stack body;
a third external electrode disposed on the second lateral surface of the filter stack body, disposed to face the second external electrode with the first external electrode interposed therebetween, and connected to the fourth coil pattern and the fifth coil pattern exposed to the second lateral surface of the filter stack body;
a fourth external electrode disposed on a first lateral surface of the filter stack body, which faces the second lateral surface of the filter stack body, and connected to a first terminal pattern and a fourth terminal pattern exposed to the first lateral surface of the filter stack body;
a fifth external electrode disposed on the first lateral surface of the filter stack body and connected to a second terminal pattern exposed to the first lateral surface of the filter stack body;
a sixth external electrode disposed on the first lateral surface of the filter stack body, disposed to face the fifth external electrode with the fourth external electrode interposed therebetween, and connected to a third terminal pattern exposed to the first lateral surface of the filter stack body;
a seventh external electrode disposed on a third lateral surface of the filter stack body and connected to a first end of the ground pattern, which is exposed to the third lateral surface of the filter stack body; and
an eighth external electrode disposed on a fourth lateral surface of the filter stack body, which faces the third lateral surface of the filter stack body, and connected to a second end of the ground pattern, which is exposed to the fourth lateral surface of the filter stack body.
